(19) United States
(12) Patent Application Publication
(10) Pub. No.: US 2015/0263150 A1
(43) Pub. Date: Sep. 17, 2015

(54) SEMICONDUCTOR DEVICE AND METHOD FOR MANUFACTURING SAME

(71) Applicant: Kabushiki Kaisha Toshiba, Tokyo (JP)

(72) Inventors: Tomoko Matsudai, Tokyo (JP); Tsuneo Ogura, Kamakura (JP); Kazutoshi Nakamura, Nonoichi (JP); Ryohei Gejo, Yokohama (JP)

(21) Appl. No.: 14/482,142

(22) Filed: Sep. 10, 2014

(30) Foreign Application Priority Data
Mar. 14, 2014 (JP) 2014-052152

(51) Int. Cl. H01L 29/739; H01L 29/10; H01L 29/66

(52) U.S. Cl. CPC H01L 29/7397; H01L 29/66348; H01L 29/1095

(57) ABSTRACT

According to one embodiment, a semiconductor device including: a first electrode; a second electrode having a portion extending toward the first electrode side; a first semiconductor layer; a first semiconductor region provided between the first semiconductor layer and the second electrode; a second semiconductor region provided between the first semiconductor region and the second electrode, and the second semiconductor region being in contact with the portion; a third electrode provided between the first electrode and the portion, and the third electrode being connected to the portion; a fourth electrode provided on the first semiconductor layer, the first semiconductor region, and the second semiconductor region via a second insulating film; and a third semiconductor region provided between the first semiconductor region and the second semiconductor region, and the third semiconductor region having a higher impurity concentration than the first semiconductor region.

### CROSS-REFERENCE TO RELATED APPLICATIONS

This application is based upon and claims the benefit of priority from Japanese Patent Application No. 2014-052152, filed on Mar. 14, 2014; the entire contents of which are incorporated herein by reference.

### FIELD

Embodiments described herein relate generally to a semiconductor device and a method for manufacturing the same.

### BACKGROUND

In semiconductor devices such as IGBTs (Insulated Gate Bipolar Transistors), large currents are controlled by switching operations. The switching operations are required to be performed in safe operation areas.

However, for instance, when carriers are excessively accumulated in a base layer at turn-off time, a parasitic thyristor formed within the semiconductor device may be turned on. In this case, gate drive is disabled and the operation within the safe operation area of the semiconductor device is no longer maintained. This may cause breakage of the semiconductor device. Therefore, it is desired to increase reliability by minimizing the excessive accumulation of carriers within the semiconductor device.

### BRIEF DESCRIPTION OF THE DRAWINGS

FIGS. 1A and 1B are schematic sectional views of a semiconductor device according to a first embodiment;

FIG. 2 is a schematic plan view of the semiconductor device according to the first embodiment;

FIGS. 3A to 13B are schematic sectional views showing a manufacturing process of the semiconductor device according to the first embodiment;

FIGS. 14A and 14B are schematic sectional views showing an example of an operation immediately after the turn-off of the semiconductor device according to the first embodiment;

FIG. 15A is a schematic sectional view of a semiconductor device according to a reference example, and FIG. 15B is a schematic sectional view of the first embodiment;

FIGS. 16A and 16B are schematic sectional views of a semiconductor device according to a variation of the first embodiment;

FIGS. 17A to 17C are schematic sectional views of a semiconductor device according to a second embodiment;

FIG. 18 is a schematic plan view of the semiconductor device according to the second embodiment;

FIG. 19 is a schematic sectional view showing an example of an operation immediately after the turn-off of the semiconductor device according to the second embodiment;

FIGS. 20A to 20C are schematic sectional views of a semiconductor device according to a first variation of the second embodiment;

FIGS. 21A to 21C are schematic sectional views of a semiconductor device according to a second variation of the second embodiment; and

FIGS. 22A to 22C are schematic sectional views of a semiconductor device according to a third variation of the second embodiment.

### DETAILED DESCRIPTION

According to one embodiment, a semiconductor device including: a first electrode; a second electrode having a portion extending toward the first electrode side; a first semiconductor layer of a first conductivity type provided between the first electrode and the second electrode; a first semiconductor region of a second conductivity type provided between the first semiconductor layer and the second electrode; a second semiconductor region of the first conductivity type provided between the first semiconductor region and the second electrode, and the second semiconductor region being in contact with the portion; a third electrode provided between the first electrode and the portion, the third electrode being provided on the first semiconductor layer, the first semiconductor region, and the second semiconductor region via a first insulating film, and the third electrode being connected to the portion; a fourth electrode provided on the first semiconductor layer, the first semiconductor region, and the second semiconductor region via a second insulating film; and a third semiconductor region of the second conductivity type provided between the first semiconductor region and the second semiconductor region, and the third semiconductor region having a higher impurity concentration than the first semiconductor region. Embodiments will be described with reference to the drawings.

In the following description, like members are labeled with like reference numerals, and the description of the members once described is omitted appropriately.

### First Embodiment

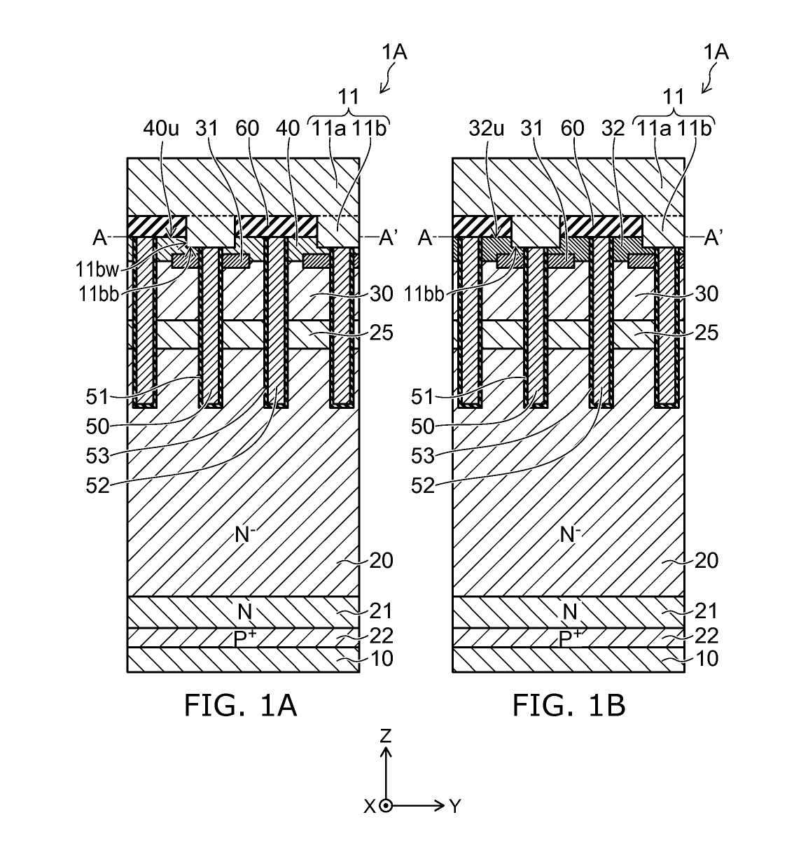

FIGS. 1A and 1B are schematic sectional views of a semiconductor device according to a first embodiment.

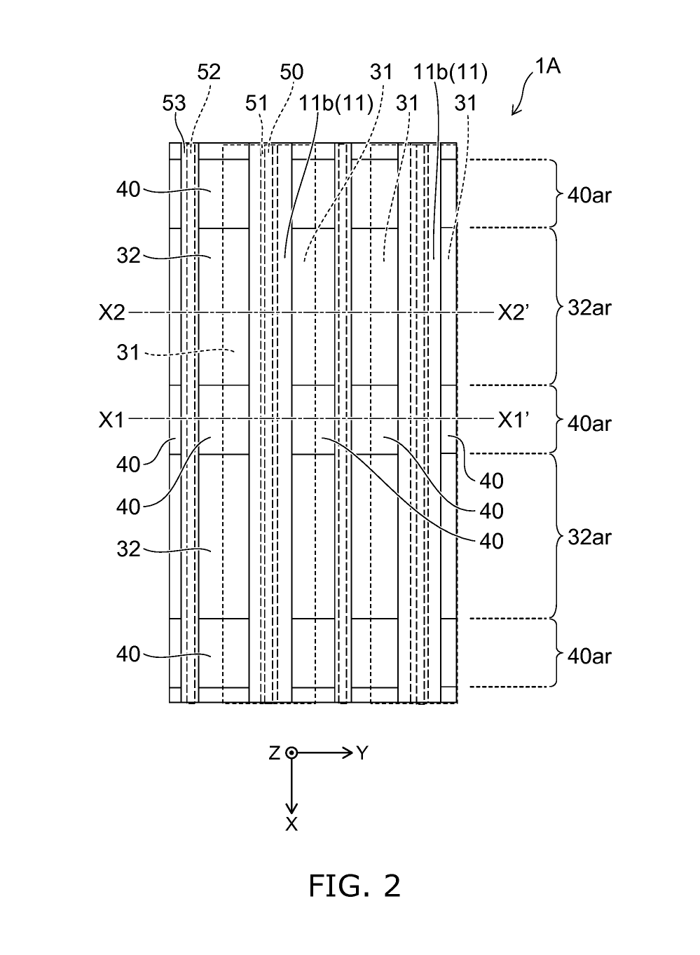

FIG. 2 is a schematic plan view of the semiconductor device according to the first embodiment.

FIG. 1A shows a cross section along line X1-X1′ in FIG. 2, and FIG. 1B shows a cross section along line X2-X2′ in FIG. 2. FIG. 2 shows a top view of the cross section along line A-A′ in FIGS. 1A, 1B. Further, FIGS. 1A, 1B and FIG. 2 show three-dimensional coordinates (X-axis, Y-axis, Z-axis). Furthermore, in the embodiments, a collector side may be referred to as a lower side and an emitter side may be referred to as an upper side.

A semiconductor device 1A is e.g. an IGBT having an upper/lower electrode structure. The semiconductor device 1A includes e.g. a collector electrode 10 (first electrode) and an emitter electrode 11 (second electrode). A p⁺-type collector region 22 (fifth semiconductor region), an n-type buffer region 21, an n⁻-type base layer 20 (first semiconductor layer), an n-type barrier region 25, a p-type base region 30 (first semiconductor region), an n⁺-type emitter region 40 (second semiconductor region), a p⁺-type diffusion region 31 (third semiconductor region), a p⁺-type contact region 32 (fourth semiconductor region), an electrode 50 (third electrode), a gate electrode 52 (fourth electrode), and an interlayer insulating film 60 are provided between the collector electrode 10 and the emitter electrode 11.

As shown in FIGS. 1A and 1B, the base layer 20 is provided between the collector electrode 10 and the emitter electrode 11. The collector region 22 is provided between the collector electrode 10 and the base layer 20. The collector region 22 is in contact with the collector electrode 10. The buffer region 21 is provided between the collector region 22 and the base layer 20. The buffer region 21 is in contact with the base layer 20 and the collector region 22.

The base region 30 is provided between the base layer 20 and the emitter electrode 11. The barrier region 25 is provided between the base region 30 and the base layer 20. The barrier region 25 is in contact with the base layer 20 and the base region 30.

The emitter electrode 11 has a portion 11a and a portion 11b. The portion 11b extends from the portion 11a toward the collector electrode 10 side. The portion 11a and the portion 11b may be an integrated part formed of the same material or parts respectively formed of different materials.

The structure of the semiconductor device 1A is described in division into the X1-X1′ cross section shown in FIG. 1A and the X2-X2′ cross section shown in FIG. 1B. The description of the same members may be omitted appropriately.

First, the X1-X1′ cross section shown in FIG. 1A is described.

In the X1-X1′ cross section, the emitter region 40 is provided between the base region 30 and the emitter electrode 11. The emitter region 40 is in contact with the base region 30 and the portion 11b of the emitter electrode 11.

The electrode 50 is located between the collector electrode 10 and the portion 11b of the emitter electrode 11. The electrode 50 is in contact with the base layer 20, the barrier region 25, the base region 30, and the emitter region 40 via an insulating film 51 (first insulating film). The electrode 50 is connected to the portion 11b of the emitter electrode 11.

The gate electrode 52 is disposed beside the electrode 50, but not located between the collector electrode 10 and the portion 11b of the emitter electrode 11. The gate electrode 52 is in contact with the base layer 20, the barrier region 25, the base region 30, and the emitter region 40 via a gate insulating film 53 (second insulating film). The gate electrode 52 is a control electrode that controls on/off operation of the semiconductor device 1A.

The diffusion region 31 containing a high-concentration impurity element is provided between the base region 30 and the emitter region 40. The diffusion region 31 is in contact with the insulating film 51. Here, at least part of the diffusion region 31 is located immediately below the portion 11b of the emitter electrode 11.

A lower portion 11bb of the portion 11b of the emitter electrode 11 is located below an upper surface 40u of the emitter region 40. In other words, the upper end of the electrode 50 is located in a position lower than the upper surface 40u of the emitter region 40. For instance, the distance between the lower portion 11bb of the portion 11b and the collector electrode 10 is shorter than the distance between the upper surface 40u of the emitter region 40 and the collector electrode 10.

Part of a side portion 11bw of the portion 11b is in contact with the emitter region 40 and the lower portion 11bb of the portion 11b is in contact with the emitter region 40. Note that the portion 11b of the emitter electrode 11 is not in contact with the diffusion region 31. The emitter region 40 is provided between the diffusion region 31 and the portion 11b of the emitter electrode 11.

The interlayer insulating film 60 is provided between the gate electrode 52 and the emitter electrode 11 and between the emitter region 40 and the emitter electrode 11.

The X2-X2′ cross section shown in FIG. 1B is described.

In the X2-X2′ cross section, the contact region 32 is provided between the base region 30 and the emitter electrode 11. The contact region 32 is in contact with the base region 30 and the portion 11b of the emitter electrode 11.

The electrode 50 is located between the collector electrode 10 and the portion 11b of the emitter electrode 11. The electrode 50 is in contact with the base layer 20, the barrier region 25, the base region 30, and the contact region 32 via the insulating film 51. The electrode 50 is connected to the portion 11b of the emitter electrode 11.

The gate electrode 52 is disposed beside the electrode 50, but not located between the collector electrode 10 and the portion 11b of the emitter electrode 11. The gate electrode 52 is in contact with the base layer 20, the barrier region 25, the base region 30, and the contact region 32 via the gate insulating film 53.

The diffusion region 31 is provided between the base region 30 and the contact region 32. The diffusion region 31 is in contact with the insulating film 51. At least part of the diffusion region 31 is located immediately below the portion 11b of the emitter electrode 11. Further, the lower portion 11bb of the portion 11b of the emitter electrode 11 is located below an upper surface 32u of the contact region 32. Note that the portion 11b of the emitter electrode 11 is not in contact with the diffusion region 31. The contact region 32 is provided between the diffusion region 31 and the portion 11b of the emitter electrode 11.

The interlayer insulating film 60 is provided between the gate electrode 52 and the emitter electrode 11 and between the contact region 32 and the emitter electrode 11.

The structure of the semiconductor device 1A is described using the plan view shown in FIG. 2.

As shown in FIG. 2, the electrode 50 and the gate electrode 52 extend in a direction crossing the Z-direction from the collector electrode 10 toward the emitter electrode 11 (e.g. the X-direction). The electrode 50 and the gate electrode 52 are alternately arranged in the Y-direction. The base region 30, the barrier region 25, the portion 11b of the emitter electrode 11, and the diffusion region 31 sandwiched between the electrode 50 and the gate electrode 52 also extend in the X-direction. Further, the electrode 50 and the gate electrode 52 may be alternately arranged in units of several electrodes, not one by one as shown in FIGS. 1A and 1B.

Furthermore, as an example, the emitter region 40 and the contact region 32 are alternately arranged in the X-direction. For instance, supposing that an area in which the emitter region 40 is disposed is an emitter disposition area 40ar and an area in which the contact region 32 is disposed is a contact disposition area 32ar, the diffusion region 31 continuously extends in the X-direction in the emitter disposition area 40ar and the contact disposition area 32ar. The diffusion region 31 is in contact with each of the emitter region 40 and the contact region 32. In addition, the emitter region 40 and the contact region 32 may be alternately and discontinuously disposed or partially disposed with each other.

Note that, in the first embodiment, the embodiment includes a structure exclusive of the barrier region 25 in the structure shown in FIGS. 1A, 1B.

Further, the impurity concentration of the diffusion region 31 and the contact region 32 is higher than the impurity concentration of the base region 30. Furthermore, the impurity concentration of the diffusion region 31 may be the same as the impurity concentration of the contact region 32 or different from the impurity concentration of the contact region 32. Preferably, the impurity concentration of the diffusion region 31 is designed to be higher than the impurity concentration of the contact region 32.

Furthermore, the n⁺-type, n-type, and n⁻-type may be referred to as first conductivity types and the p⁺-type and p-type may be referred to as second conductivity types. Here, the impurity concentration is lower in the order of the n⁺-type, n-type, n⁻-type and the order of the p⁺-type and p-type.

The above described “impurity concentration” refers to the effective concentration of the impurity element contributing to the conductivity of the semiconductor material. For instance, in the case where the semiconductor material contains an impurity element serving as a donor and an impurity element serving as an acceptor, the impurity concentration is defined as the concentration of the activated impurity elements exclusive of the donor and the acceptor canceling out each other.

The major component of each of the collector region 22, the buffer region 21, the base layer 20, the barrier region 25, the base region 30, the emitter region 40, the diffusion region 31, and the contact region 32 is e.g. silicon (Si). The impurity element of the first conductivity type is e.g. phosphorous (P), arsenic (As), or the like. The impurity element of the second conductivity type is e.g. boron (B) or the like. Furthermore, these major components may be silicon carbide (SiC), gallium nitride (GaN), or the like in addition to silicon (Si).

The materials of the collector electrode 10 and the emitter electrode 11 are metals including at least one selected from the group consisting of e.g. aluminum (Al), titanium (Ti), nickel (Ni), tungsten (W), gold (Au) etc. Further, the material of the portion 11b of the emitter electrode 11 may be e.g. polysilicon doped with an impurity element.

The electrode 50 and the gate electrode 52 include polysilicon doped with an impurity element, metals, or the like. Further, in the embodiments, the insulating film is an insulating film containing e.g. silicon oxide (SiOₓ), silicon nitride (SiNₓ), or the like.

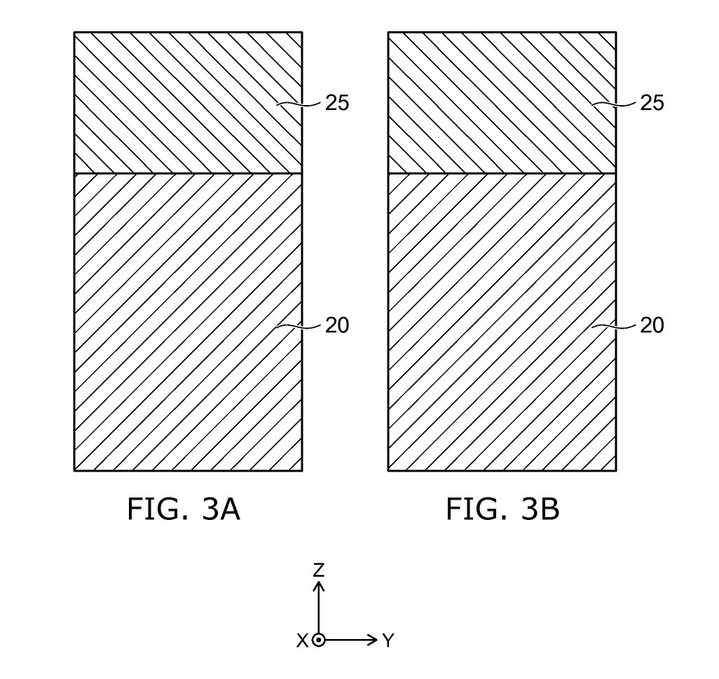

FIGS. 3A to 13B are schematic sectional views showing a manufacturing process of the semiconductor device according to the first embodiment.

Here, of FIGS. 3A to 13B, the respective figures A show cross sections in the position of line X1-X1′ and the respective figures B show cross sections in the position of line X2-X2′. In other words, the respective figures A show cross sections in the emitter disposition area 40ar and the respective figures B show cross sections in the contact disposition area 32ar.

First, as shown in FIGS. 3A, 3B, the n⁻-type base layer 20 is prepared. Subsequently, a first conductivity-type impurity element is implanted into the surface layer of the base layer 20. Then, heat treatment is performed thereon. Thereby, the barrier region 25 is formed in the surface layer of the base layer 20. Here, the base layer 20 and the barrier region 25 are collectively referred to as a semiconductor layer.

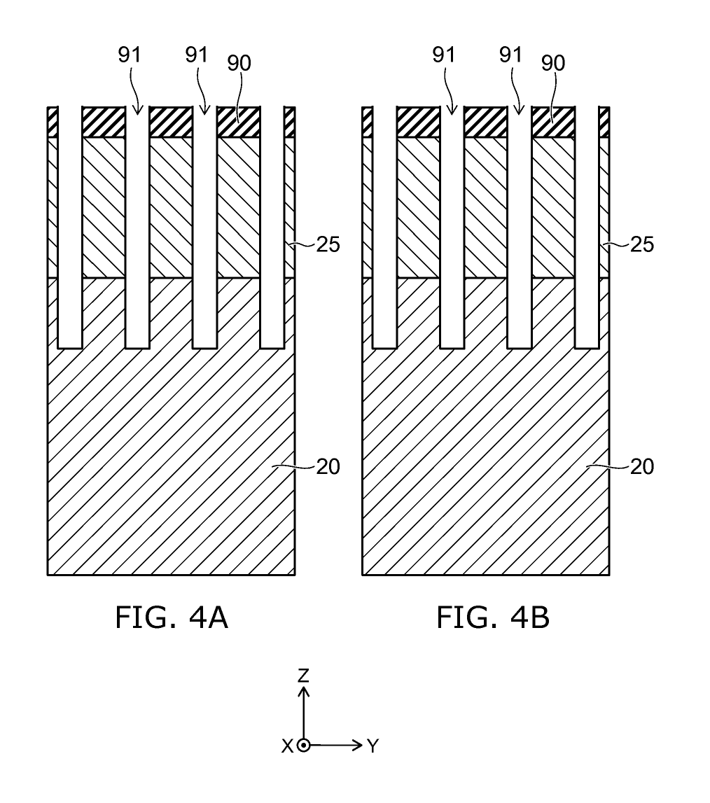

Then, as shown in FIGS. 4A, 4B, a mask layer 90 is selectively formed on the barrier region 25. Subsequently, the barrier region 25 exposed from the mask layer 90 and the base layer 20 below the barrier region is etched by RIE (Reactive Ion Etching). Thereby, a plurality of trenches 91 are formed from the front surface toward the rear surface of the semiconductor layer. The respective trenches 91 are dug down in the Z-direction and further extend in the X-direction. Further, the respective trenches 91 are arranged in the Y-direction.

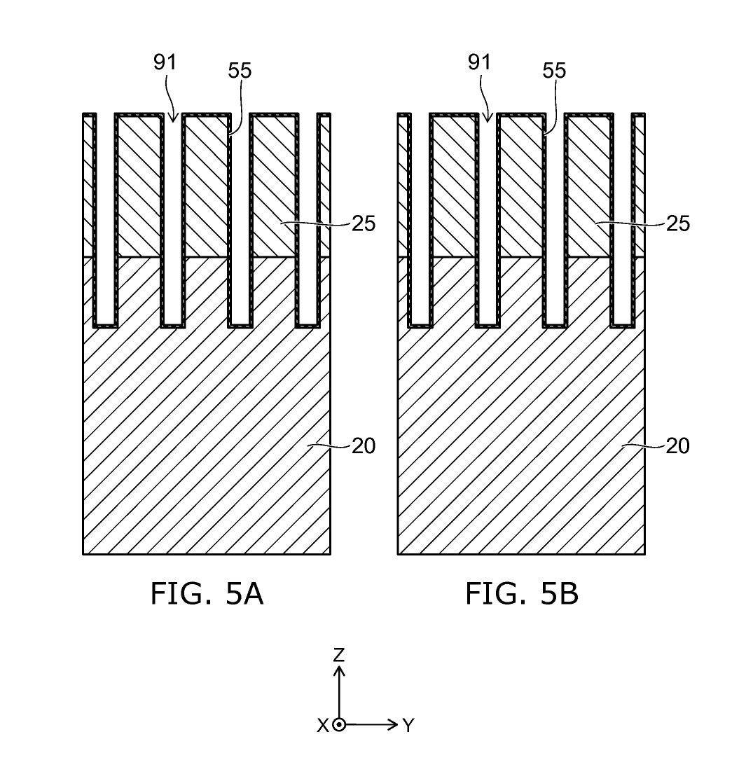

Then, as shown in FIGS. 5A, 5B, an insulating film 55 is formed on the inner walls of the trenches 91 and the upper layer of the barrier region 25 by one method of thermal oxidation, CVD (Chemical Vapor Deposition), and sputtering.

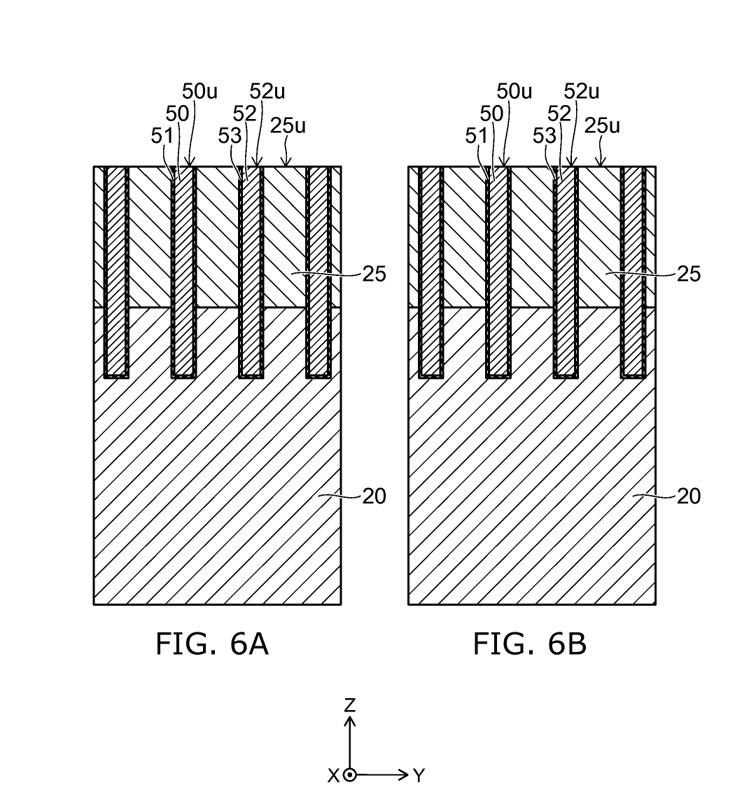

Then, as shown in FIGS. 6A, 6B, electrodes 50 are formed in a first group of the trenches 91 via the insulating films 51 and gate electrodes 52 are formed in a second group of the trenches 91 via the gate insulating films 53. The first group of trenches 91 and the second group of trenches 91 are alternately arranged in the Y-direction.

The electrodes 50 and the gate electrodes 52 are formed by CVD and the material of the electrodes 50 and the material of the gate electrodes 52 are the same. Further, e.g. CMP (Chemical Mechanical Polishing) processing is performed on excess coatings formed on the upper side than the upper surface 25u of the barrier region 25 (not shown).

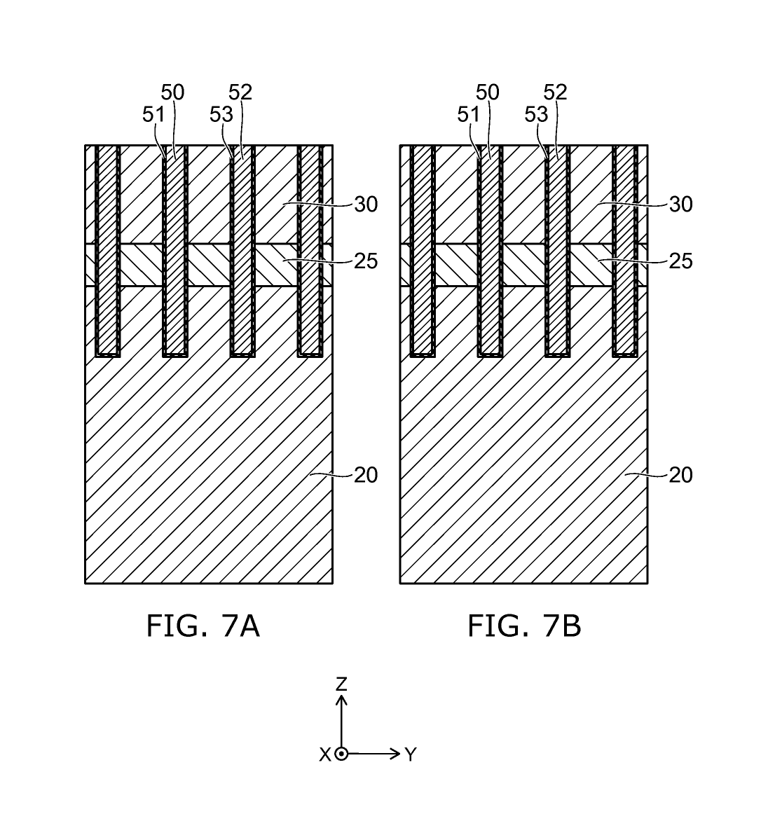

Then, as shown in FIGS. 7A, 7B, a second conductivity-type impurity element is implanted into the surface layer of the barrier region 25. Then, heat treatment is performed thereon. Thereby, the base region 30 is formed in the surface layer of the barrier region 25.

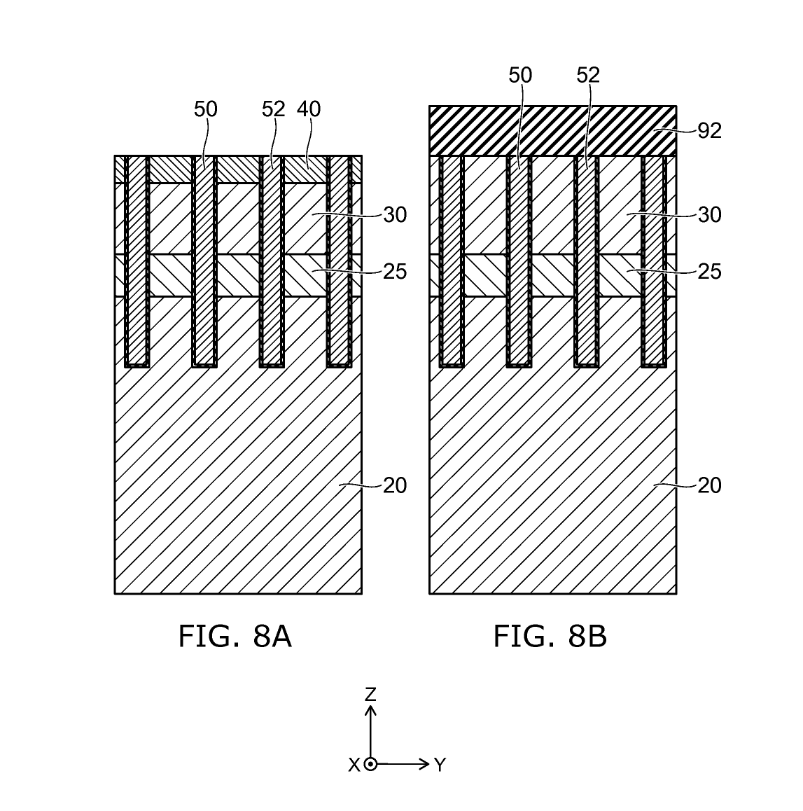

Then, as shown in FIG. 8A, in the X1-X1′ cross section, a first conductivity-type impurity element is selectively implanted into the surface layer of the base region 30. Then, heat treatment is performed thereon. Thereby, the emitter region 40 is formed in the surface layer of the base region 30. Here, in the X2-X2′ cross section shown in FIG. 8B, the surface of the base region 30 is covered by a mask layer 92. Therefore, in the X2-X2′ cross section, the first conductivity-type impurity element is not implanted into the surface layer of the base region 30.

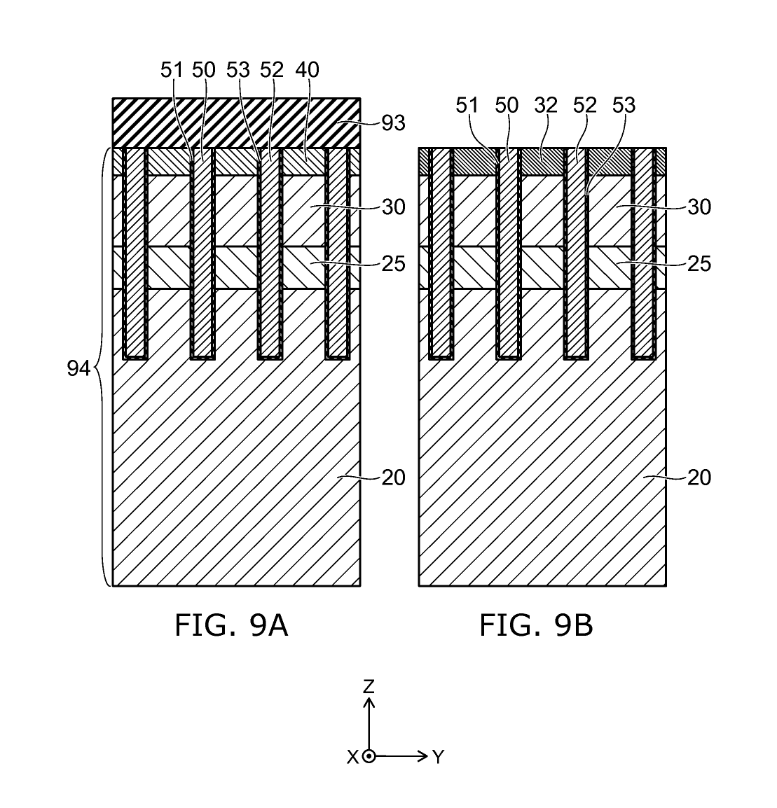

Then, as shown in FIG. 9B, in the X2-X2′ cross section, a second conductivity-type impurity element is selectively implanted into the surface layer of the base region 30. Then, heat treatment is performed thereon. Thereby, the contact region 32 is formed in the surface layer of the base region 30. Here, in the X1-X1′ cross section shown in FIG. 9A, the surface of the emitter region 40 is covered by a mask layer 93. Therefore, in the X1-X1′ cross section, the second conductivity-type impurity element is not implanted into the surface layer of the emitter region 40. Then, the mask layer 93 is removed.

At the stage, a structure 94 containing a plurality of semiconductor layers or a plurality of semiconductor regions is prepared. In the structure 94, the base region 30 is provided in the surface layer of the barrier region 25 and the emitter region 40 is selectively provided in the surface layer of the base region 30. Further, in the structure 94, the electrodes 50 and the gate electrodes 52 are provided.

Note that the order of the processes from FIGS. 4A, 4B to FIGS. 9A, 9B is not limited to the above described example. For instance, the structure of the base layer 20/barrier region 25/base region 30/emitter region 40 and the contact region 32 may be formed, then, the plurality of the trenches 91 may be formed, and the electrodes 50 and the gate electrodes 52 may be formed.

Further, the embodiment includes the manufacturing process without formation of the barrier region 25. In this case, the base region 30 is once formed in the surface layer of the base layer 20, and then, the emitter region 40 and the contact region 32 are further formed in the surface layer of the base region 30.

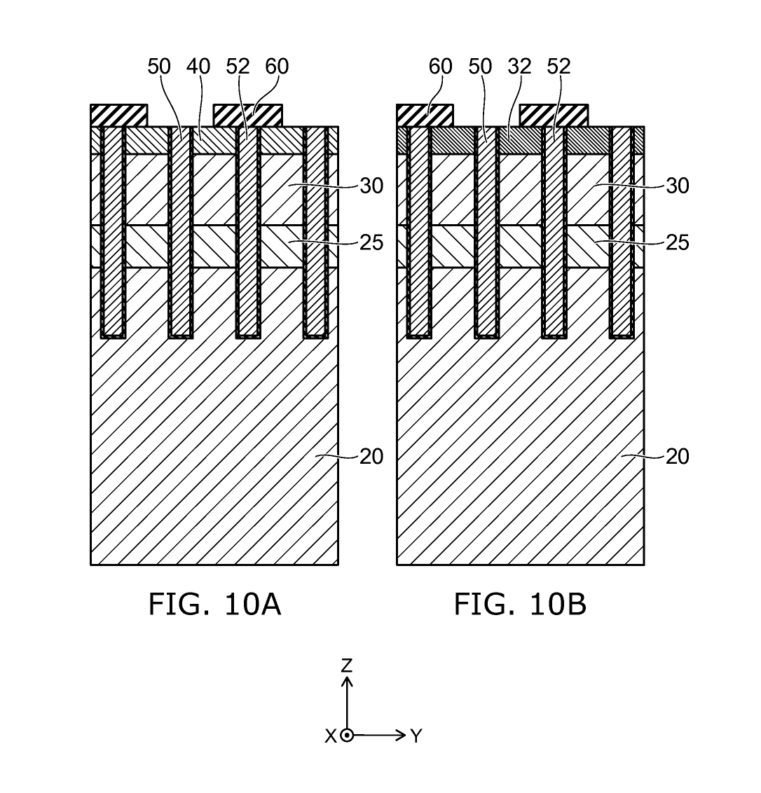

Then, as shown in FIG. 10A, in the X1-X1′ cross section, interlayer insulating films 60 that cover the gate electrodes 52, the gate insulating films 53, and parts of the emitter region 40 sandwiching the gate electrodes 52 are formed on the emitter region 40 and the gate electrodes 52. The interlayer insulating films 60 open the electrodes 50, the insulating films 51, and the emitter region 40 exclusive of the parts of the emitter region 40 covered by the interlayer insulating films 60.

Further, as shown in FIG. 10B, in the X2-X2′ cross section, the interlayer insulating films 60 that cover the gate electrodes 52, the gate insulating films 53, and parts of the contact region 32 sandwiching the gate electrodes 52 are formed on the contact region 32 and the gate electrodes 52. The interlayer insulating films 60 open the electrodes 50, the insulating films 51, and the contact region 32 exclusive of the parts of the contact region 32 covered by the interlayer insulating films 60.

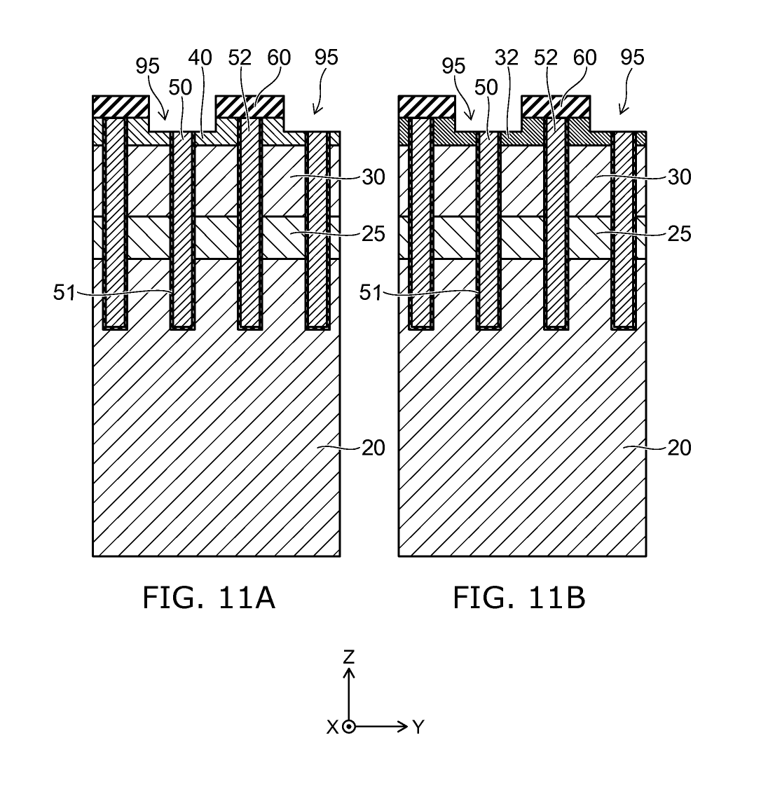

The interlayer insulating films 60 continuously extend in the X-direction in the emitter disposition area 40ar and the contact disposition area 32ar. The formation of the interlayer insulating films 60 shown in FIGS. 10A, 10B are performed at the same time. Then, as shown in FIG. 11A, in the X1-X1′ cross section, the emitter region 40, the electrodes 50, and the insulating films 51 exposed from the interlayer insulating films 60 are etched by RIE using the interlayer insulating films 60 as masks. Thereby, trenches 95 having the emitter region 40, the electrodes 50, and the insulating films 51 as bottom portions 95b are formed.

Further, as shown in FIG. 11B, in the X2-X2′ cross section, the contact region 32, the electrodes 50, and the insulating films 51 exposed from the interlayer insulating films 60 are etched by RIE using the interlayer insulating films 60 as masks. Thereby, trenches 95 having the contact region 32, the electrodes 50, and the insulating films 51 as bottom portions 95b are formed.

The trenches 95 formed by RIE continuously extend in the X-direction in the emitter disposition area 40ar and the contact disposition area 32ar. The RIE shown in FIGS. 11A, 11B is performed at the same time.

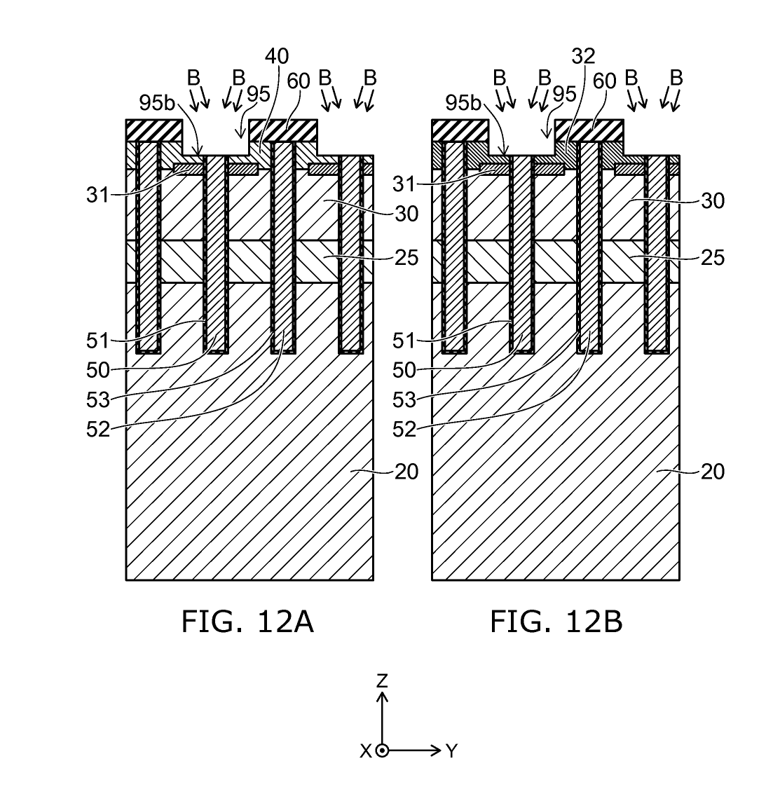

Then, as shown in FIG. 12A, in the X1-X1′ cross section, a second conductivity-type impurity element (e.g. boron (B)) is implanted between the base region 30 and the emitter region 40 via the trenches 95. In the ion implantation, ion implantation perpendicularly to the injection surface or the so-called oblique ion implantation of ion implantation at a predetermined angle from the normal line of the injection surface may be used. Thereby, the second conductivity-type impurity element infiltrates not only to the sides under the trenches 95 but also to the sides under the interlayer insulating films 60. Further, in the ion implantation, a high acceleration energy condition is set so that the diffusion region 31 may be formed between the base region 30 and the emitter region 40, i.e., the emitter region 40 may reliably intervene between the lower portion 11bb of the portion 11b of the emitter electrode 11 and the diffusion region 31.

Further, as shown in FIG. 12B, in the X2-X2′ cross section, a second conductivity-type impurity element (e.g. boron (B)) is implanted between the base region 30 and the contact region 32 via the trenches 95. In the ion implantation, the so-called oblique ion implantation may be used. Thereby, the second conductivity-type impurity element infiltrates not only to the sides under the trenches 95 but also to the sides under the interlayer insulating films 60. Further, in the ion implantation, a high acceleration energy condition is set so that the diffusion region 31 may be formed between the base region 30 and the emitter region 40.

Then, heat treatment is performed thereon. Thereby, the diffusion regions 31 are formed between the base region 30 and the emitter region 40 and between the base region 30 and the contact region 32. Note that heating at the stage is heating for activation such as RTA (Rapid Thermal Anneal), and it is not favorable that thermal diffusion processing of diffusing the implanted impurity element over the wider range of the semiconductors is performed. Thereby, the diffusion regions 31 are located between the base region 30 and the emitter region 40 and between the base region 30 and the contact region 32. The ion implantation shown in FIGS. 12A, 12B is performed at the same time.

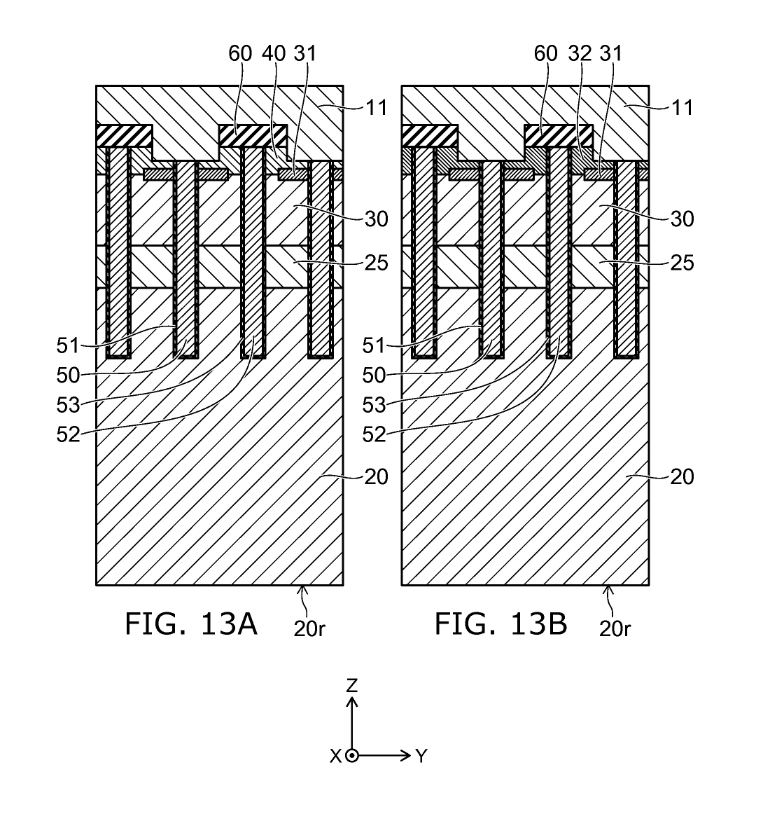

Then, as shown in FIGS. 13A, 13B, the emitter electrode 11 is formed inside of the trenches 95 and on the interlayer insulating films 60. Then, a first conductivity-type impurity element is implanted from the side of a rear surface 20r of the base layer 20 and the buffer region 21 is formed. Subsequently, a second conductivity-type impurity element is implanted from the side of the rear surface 20r of the base layer 20 and the collector region is formed. Furthermore, the collector electrode 10 is formed. The state after the formation of the collector electrode 10 has been already shown in FIGS. 1A, 1B.

The operation of the semiconductor device 1A is explained.

In the semiconductor device 1A shown in FIGS. 1A, 1B, a higher potential is applied to the collector electrode 10 than that to the emitter electrode 11. Further, a voltage not less than a threshold voltage (Vth) is applied to the gate electrode 52, a channel region (inversion layer) is formed in the base region 30 along the gate insulating film 53 and the semiconductor device 1A turns to an on-state (turn-on).

In the on-state, electrons are injected from the emitter region 40 into the base region 30 and an electron current flows in the order of the barrier region 25, the base layer 20, the buffer region 21, the collector region 22, and the collector electrode 10. On the other hand, holes are injected from the collector region 22 into the buffer region 21, and a hole current flows in the order of the base layer 20, the barrier region 25, the base region 30, the contact region 32 or the emitter region 40, and the emitter electrode 11.

In the semiconductor device 1A, the emitter region 40 is not provided in the whole area of the semiconductor device 1A at the emitter side. For instance, in the semiconductor device 1A, the emitter region 40 and the contact region 32 are alternately provided in the X-direction on the base region 30. Further, the electrode 50 disposed between the adjacent gate electrodes 52 does not function as a gate electrode. That is, in the semiconductor device 1A, the channel density is appropriately adjusted and the saturation current value is controlled.

Furthermore, in the semiconductor device 1A, the emitter region 40 is in contact not only with the side portion 11bw of the portion 11b of the emitter electrode 11 but also with the lower portion 11bb of the portion 11b. Therefore, in the semiconductor device 1A, compared to the structure in which the emitter region 40 is in contact only with the side portion 11bw of the portion 11b, the electrical contact between the emitter region 40 and the portion 11b is improved. That is, the contact resistance between the emitter region 40 and the emitter electrode 11 is further reduced.

On the other hand, in the gate electrode 52, when the application voltage becomes lower to a voltage smaller than the threshold voltage (Vth), the channel region disappears and the semiconductor device 1A turns to an off-state (turn-off). However, in the IGBT, when turning to the off-state, IGBT may improperly operate due to the accumulated carriers (holes). For instance, a parasitic npn-transistor (n⁺-type emitter region 40/p-type base region 30/n-type barrier region 25) may operate as an element. When the parasitic npn-transistor operates, the so-called latch-up occurs and the gate drive is disabled, and the IGBT may break. Therefore, in the IGBT, it is desired that, after turn-off, the holes accumulated within the element are rapidly ejected to the emitter electrode 11.

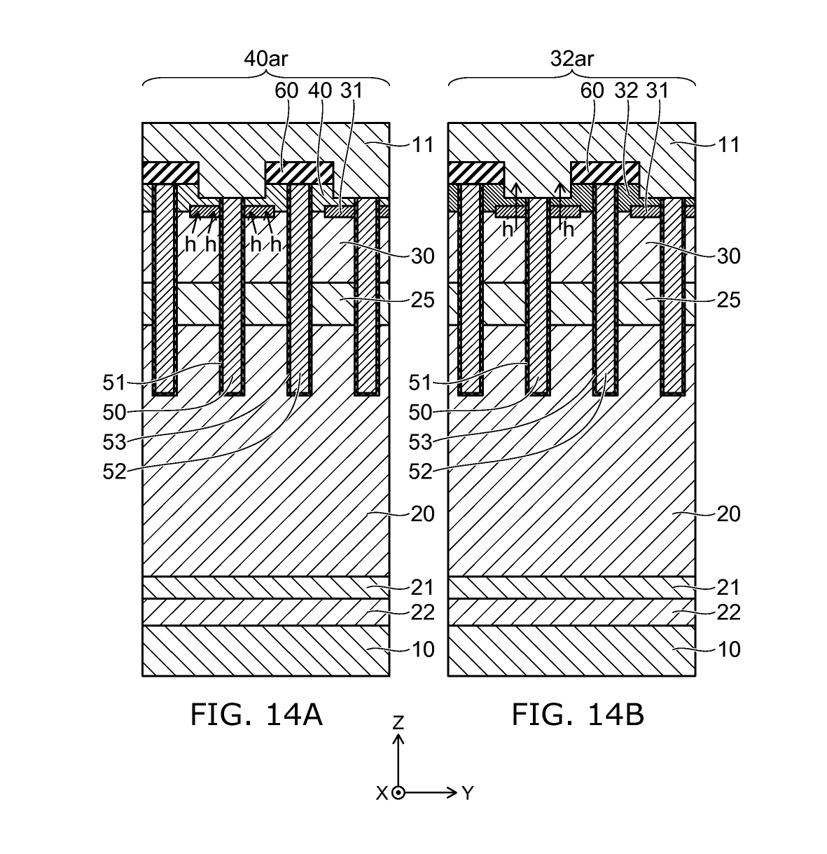

FIGS. 14A and 14B are schematic sectional views showing an example of an operation immediately after the turn-off of the semiconductor device according to the first embodiment.

In the semiconductor device 1A, the diffusion region 31 is provided immediately below the portion 11b of the emitter electrode 11. The diffusion region 31 continuously extends in the X-direction in the emitter disposition area 40ar and the contact disposition area 32ar (FIG. 2).

In the emitter disposition area 40ar shown in FIG. 14A, immediately after the turn-off, holes (h) flow into the p⁺-type diffusion region 31 with the higher impurity concentration and the lower resistance (arrows in FIG. 14A). Note that, in the junction part between the p⁺-type diffusion region 31 and the emitter region 40, an energy barrier for the holes (h) is formed. Therefore, in the emitter disposition area 40ar, a current path in which the holes (h) are ejected to the emitter electrode 11 via the emitter region 40 is harder to be formed. However, the holes (h) flowing into the diffusion region 31 move within the diffusion region 31 and reach the contact region 32. Here, the movement of the holes (h) within the diffusion region 31 is hole transportation in the X-direction of the drawing. Then, the holes (h) reach the diffusion region 31 in contact with the contact region 32 and ejected to the emitter electrode 11 in contact with the contact region 32.

On the other hand, in the contact disposition area 32ar shown in FIG. 14B, immediately after the turn-off, holes (H) flow into the p⁺-type diffusion region 31. The holes (h) flowing into the diffusion region 31 are ejected to the emitter electrode 11 via the p⁺-type contact region 32 immediately above (arrows in FIG. 14B).

As described above, in the semiconductor device 1A, in the emitter disposition area 40ar and the contact disposition area 32ar, the holes (h) are rapidly ejected to the emitter electrode 11 immediately after the turn-off. Thereby, in the semiconductor device 1A, the operation of the parasitic npn-transistor after turn-off is suppressed and latch-up is harder to occur. As a result, the semiconductor device 1A has high breakdown withstand capability.

Here, the resistance between the portion 11b of the emitter electrode 11 and the base region 30 is considered.

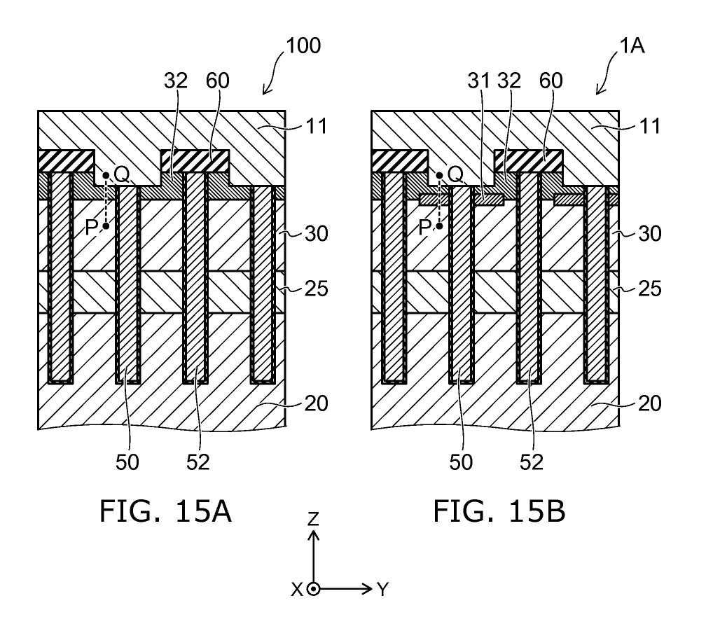

FIG. 15A is a schematic sectional view of a semiconductor device according to a reference example, and FIG. 15B is a schematic sectional view of the first embodiment.

FIGS. 15A, 15B show the cross sections of the contact disposition areas 32ar.

No diffusion region 31 is provided in a semiconductor device 100 shown in FIG. 15A. Therefore, the resistance between points P and Q shown in FIG. 15A is a series resistance of the resistance of the base region 30, the resistance of the contact region 32, and the resistance of the emitter electrode 11 existing between the points P-Q.

On the other hand, in the semiconductor device 1A shown in FIG. 15B, the diffusion region 31 is provided. Therefore, the resistance between the points P-Q shown in FIG. 15B is a series resistance of the resistance of the base region 30, the resistance of the diffusion region 31, the resistance of the contact region 32, and the resistance of the emitter electrode 11 existing between the points P-Q. Further, in the semiconductor device 1A, part of the base region 30 and part of the contact region 32 are replaced by the diffusion region 31. Here, the resistivity of the diffusion region 31 is lower than the resistivity of the base region 30.

Therefore, the resistance between the points P-Q of the semiconductor device 1A is lower than the resistance between the points P-Q of the semiconductor device 100. Therefore, in the semiconductor device 1A, immediately after the turn-off, the holes (h) are efficiently ejected to the emitter electrode 11 via the base region 30, the diffusion region 31, and the contact region 32.

Further, the electrode 50 is connected to the emitter electrode 11 and, in either of the on-state or the off-state, the potential does not vary, but the stable potential is maintained.

As described above, according to the first embodiment, the highly reliable semiconductor device 1A with the element harder to be broken is provided.

Further, in the example, the n-type barrier region 25 is not necessarily required. Without the barrier region 25, the same advantage as described above may be obtained.

### (Variation of First Embodiment)

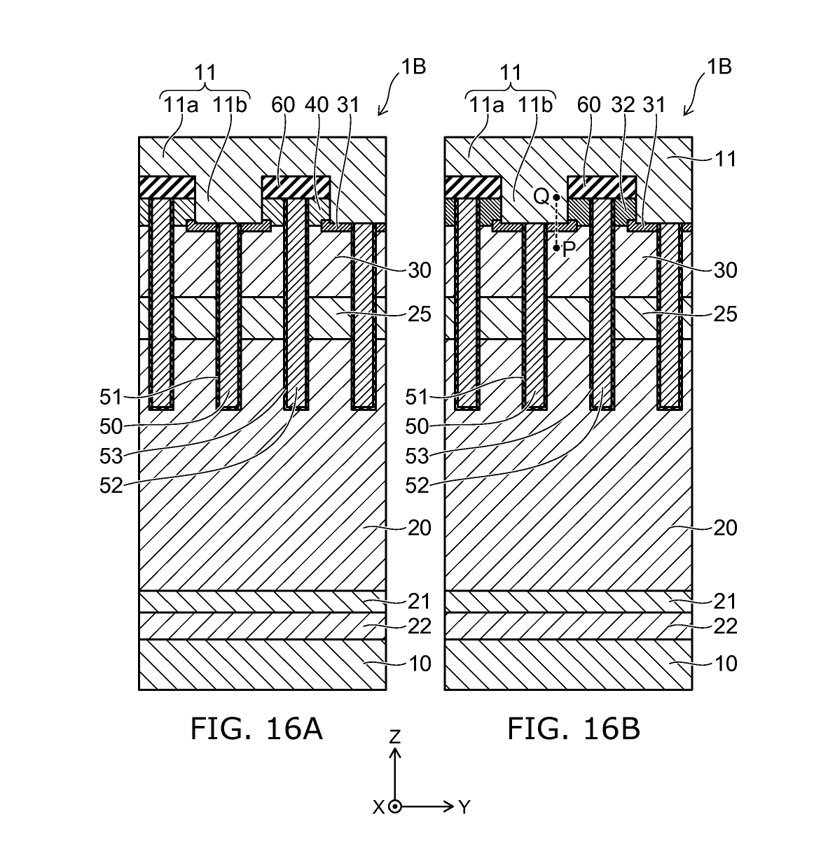

FIGS. 16A and 16B are schematic sectional views of a semiconductor device according to a variation of the first embodiment.

FIG. 16A shows a cross section in the position of line X1-X1′ and FIG. 16B shows a cross section in the position of line X2-X2′.

A semiconductor device 1B has the component elements of the semiconductor device 1A. Note that, in the semiconductor device 1B, the portion 11b of the emitter electrode 11 further extends toward the collector side compared to the portion 11b of the emitter electrode of the semiconductor device 1A. For instance, the portion 11b of the emitter electrode 11 of the semiconductor device 1B is in contact with the diffusion region 31.

In the structure, the resistance between the points P-Q is further lowered than the resistance between the points P-Q of the semiconductor device 1A. Therefore, the ejection efficiency of the holes (h) to the emitter electrode 11 further increases compared to that in the semiconductor device 1A. That is, according to the semiconductor device 1B, the operation of the parasitic npn-transistor is further suppressed compared to that of the semiconductor device 1A. As a result, the semiconductor device 1B has the higher breakdown withstand capability than that of the semiconductor device 1A.

Further, in the example, the n-type barrier region 25 is not necessarily required. Without the barrier region 25, the same advantage as described above may be obtained.

### Second Embodiment

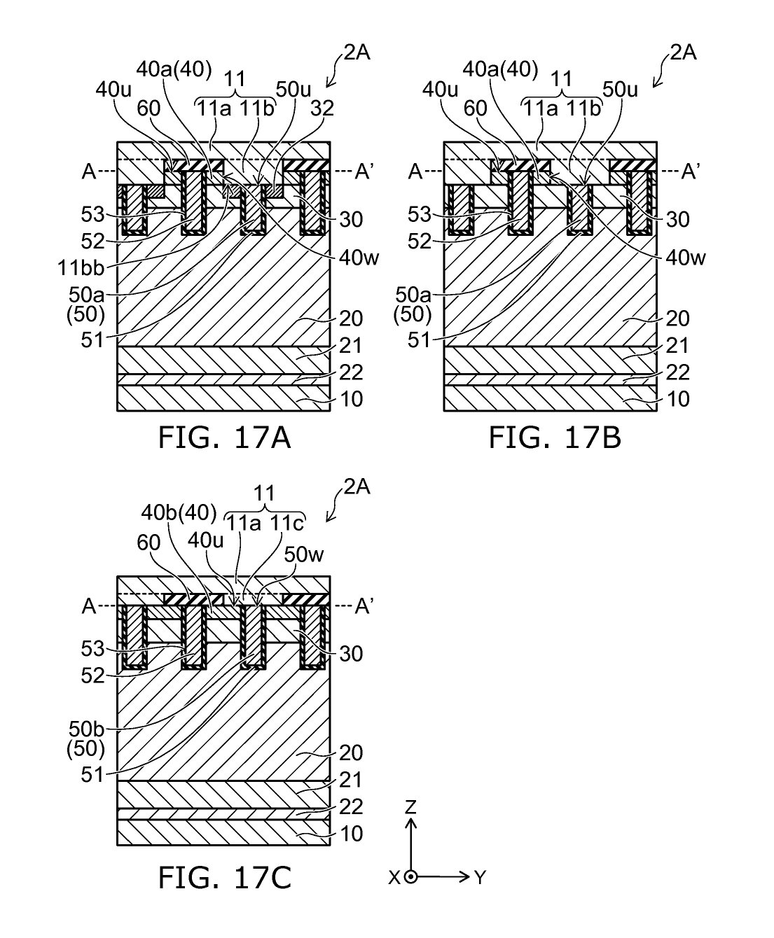

FIGS. 17A to 17C are schematic sectional views of a semiconductor device according to a second embodiment.

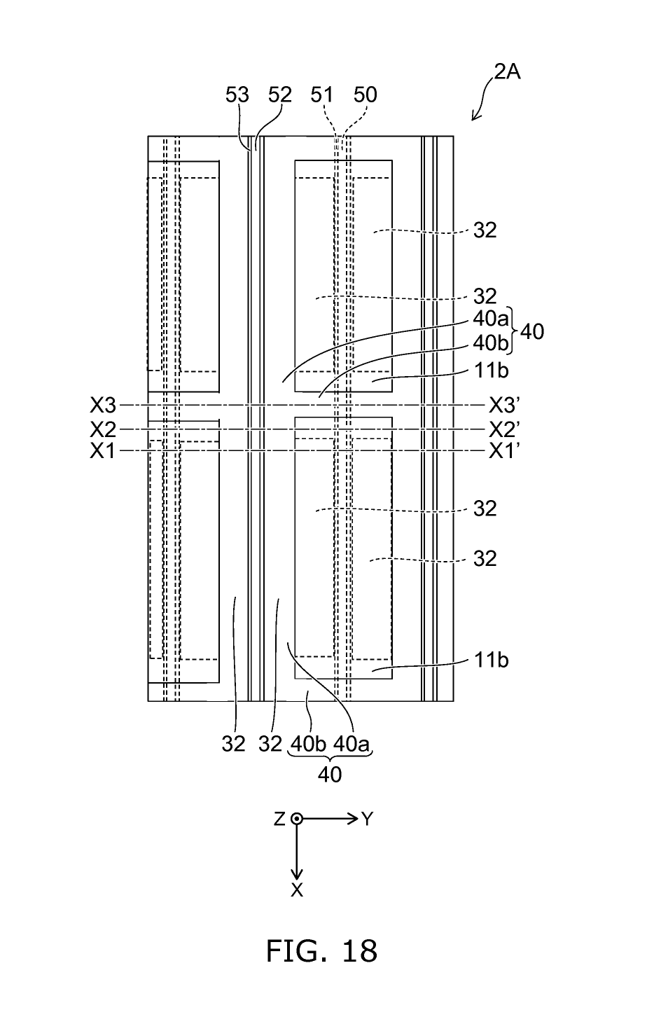

FIG. 18 is a schematic plan view of the semiconductor device according to the second embodiment.

FIG. 17A shows a cross section along line X1-X1′ in FIG. 18, FIG. 17B shows a cross section along line X2-X2′ in FIG. 18, and FIG. 17C shows a cross section along line X3-X3′ in FIG. 18. FIG. 18 shows a top view of the cross section along line A-A′ in FIGS. 17A to 17C.

The semiconductor device 2A includes e.g. a collector electrode 10 and an emitter electrode 11. A p⁺-type collector region 22, an n-type buffer region 21, an n⁻-type base layer 20, a p-type base region 30, an n⁺-type emitter region 40, a p⁺-type contact region 32, an electrode 50, a gate electrode 52, and an interlayer insulating film 60 are provided between the collector electrode 10 and the emitter electrode 11.

In FIGS. 17A to 17C, the above described n-type barrier region 25 is not shown. A barrier region 25 may be provided in the semiconductor device 2A.

In the semiconductor device 2A, the base layer 20 is provided between the collector electrode 10 and the emitter electrode 11. The collector region 22 is provided between the base layer 20 and the collector electrode 10. The buffer region 21 is provided between the collector region 22 and the base layer 20. The base region 30 is provided between the base layer 20 and the emitter electrode 11.

In the second embodiment, the emitter electrode 11 has a portion 11a, a portion 11b (FIGS. 17A, 17B), and a portion 11c (FIG. 17C). The portion 11b and the portion 11c extend from the portion 11a toward the collector electrode 10 side. The thickness of the portion 11c is smaller than the thickness of the portion 11b. The portion 11a, the portion 11b, and the portion 11c may be an integrated part formed of the same material or parts respectively formed of different materials.

Further, in the second embodiment, the emitter region 40 has a first region 40a (FIGS. 17A, 17B) and a second region 40b (FIG. 17C). The emitter region 40 is provided between the base region 30 and the emitter electrode 11. The first region 40a and the second region 40b are integrated.

Furthermore, in the second embodiment, the electrode 50 has a first electrode portion 50a (FIGS. 17A, 17B) and a second electrode portion 50b (FIG. 17C). The electrode 50 is located between the collector electrode 10 and the portion 11b and the portion 11c of the emitter electrode 11. The first electrode portion 50a and the second electrode portion 50b are integrated.

The structure of the upper layer of the semiconductor device 2A is described in division into the X1-X1′ cross section shown in FIG. 17A, the X2-X2′ cross section shown in FIG. 17B, and the X3-X3′ cross section shown in FIG. 17C. The description of the same members may be omitted appropriately.

First, the X1-X1′ cross section shown in FIG. 17A is described.

In the X1-X1′ cross section, the first region 40a of the emitter region 40 is in contact with the base region 30 and the portion 11b of the emitter electrode 11. For instance, a side portion 40w of the first region 40a of the emitter region 40 is connected to the portion 11b of the emitter electrode 11. Note that the lower portion 11bb of the portion 11b of the emitter electrode 11 is in contact with the contact region 32.

The first electrode portion 50a of the electrode 50 is located between the collector electrode 10 and the portion 11b of the emitter electrode 11. An upper surface 50u of the first electrode portion 50a is in a position lower than an upper surface 40u of the emitter region 40. The first electrode portion 50a is in contact with the base layer 20, the base region 30, and the contact region 32 via an insulating film 51. The first electrode portion 50a is connected to the portion 11b of the emitter electrode 11.

The gate electrode 52 is disposed beside the first electrode portion 50a of the electrode 50, but not located between the collector electrode 10 and the portion 11b of the emitter electrode 11. The gate electrode 52 is in contact with the base layer 20, the base region 30, and the emitter region 40 via a gate insulating film 53.

The contact region 32 is provided between the base region 30 and the portion 11b of the emitter electrode 11. The contact region 32 is in contact with the insulating film 51. The contact region 32 is located immediately below the portion 11b of the emitter electrode 11.

The interlayer insulating film 60 is provided between the gate electrode 52 and the emitter electrode 11 and between the emitter region 40 and the emitter electrode 11.

The X2-X2′ cross section shown in FIG. 17B is described.

In the X2-X2′ cross section, the first region 40a of the emitter region 40 is in contact with the base region 30 and the portion 11b of the emitter electrode 11. For instance, the side portion 40w of the first region 40a of the emitter region 40 is connected to the portion 11b of the emitter electrode 11. The lower portion 11bb of the portion 11b of the emitter electrode 11 is in contact with the base region 30.

The first electrode portion 50a of the electrode 50 is located between the collector electrode 10 and the portion 11b of the emitter electrode 11. The upper surface 50u of the first electrode portion 50a is located in a position lower than the upper surface 40u of the emitter region 40. The first electrode portion 50a is in contact with the base layer 20 and the base region 30 via the insulating film 51. The first electrode portion 50a is connected to the portion 11b of the emitter electrode 11.

The gate electrode 52 is disposed beside the first electrode 50a, but not located between the collector electrode 10 and the portion 11b of the emitter electrode 11. The gate electrode 52 is in contact with the base layer 20, the base region 30, and the emitter region 40 via the gate insulating film 53.

The X3-X3′ cross section shown in FIG. 17C is described.

In the X3-X3′ cross section, the second region 40b of the emitter region 40 is in contact with the base region 30 and the portion 11c of the emitter electrode 11. For instance, an upper portion 40u of the second region 40b of the emitter region 40 is connected to the portion 11c of the emitter electrode 11.

The second electrode portion 50b of the electrode 50 is located between the collector electrode 10 and the portion 11c of the emitter electrode 11. An upper surface 50u of the second electrode portion 50b is located at the same height as that of the upper surface 40u of the emitter region 40. That is, the height of the first electrode portion 50a and the height of the second electrode portion 50b are different and the height of the second electrode portion 50b is lower than the height of the first electrode portion 50a. The second electrode portion 50b is in contact with the base layer 20, the base region 30, and the second region 40b of the emitter region 40 via the insulating film 51. The second electrode portion 50b is connected to the portion 11c of the emitter electrode 11.

The gate electrode 52 is disposed beside the second electrode portion 50b, but not located between the collector electrode 10 and the portion 11c of the emitter electrode 11. The gate electrode 52 is in contact with the base layer 20, the base region 30, and the emitter region 40 via the gate insulating film 53.

The structure of the semiconductor device 2A is described using the plan view shown in FIG. 18.

As shown in FIG. 18, the electrode 50 and the gate electrode 52 extend e.g. in the X-direction. The electrode 50 and the gate electrode 52 are alternately arranged in the Y-direction. The portion 11b of the emitter electrode 11 and the contact region 32 sandwiched between the electrode 50 and the gate electrode 52 also extend in the X-direction.

Further, the second region 40b of the emitter region 40 and the contact region 32 are alternately arranged in the X-direction. As described above, the emitter region 40 has the first region 40a and the second region 40b. The contact region 32 is in contact with the emitter region 40.

In the semiconductor device 2A, a higher potential is applied to the collector electrode 10 than that to the emitter electrode 11. When a voltage not less than a threshold voltage is applied to the gate electrode 52, a channel region is formed in the base region 30 along the gate insulating film 53 and the semiconductor device 2A turns to an on-state.

In the on-state, electrons are injected from the emitter region 40 (40a, 40b) into the base region 30 and an electron current flows in the order of the base layer 20, the buffer region 21, the collector region 22, and the collector electrode 10. On the other hand, holes are injected from the collector region 22 into the buffer region 21 and a hole current flows in the order of the barrier region 25, the base layer 20, the base region 30, the contact region 32 or the emitter region 40, and the emitter electrode 11.

In the semiconductor device 2A, the emitter region 40 is not provided in the whole area at the emitter side. For instance, in the semiconductor device 2A, the second region 40b of the emitter region 40 and the contact region 32 are alternately provided in the X-direction on the base region 30. Further, the electrode 50 disposed between the adjacent gate electrodes 52 does not function as a gate electrode. That is, in the semiconductor device 2A, the channel density is appropriately adjusted and the saturation current value is controlled so that the current conducted between emitter/collector in the on-state may not lead to element breakage.

Further, in the semiconductor device 2A, the first region 40a of the emitter region 40 is in contact with the emitter electrode 11 and the second region 40b of the emitter region 40 is in contact with the emitter electrode 11. For instance, the side portion 40w of the first region 40a of the emitter region 40 is in contact with the emitter electrode 11 and the upper surface 40u of the second region 40b is in contact with the emitter electrode 11.

Therefore, in the semiconductor device 2A, compared to the structure in which only the side portion 40w of the first region 40a of the emitter region 40 is in contact with the emitter electrode 11, the electrical contact between the emitter region 40 and the emitter electrode 11 is improved. That is, the contact resistance between the emitter region 40 and the emitter electrode 11 is further reduced.

On the other hand, when a voltage smaller than the threshold voltage is applied to the gate electrode 52, the channel region disappears and the semiconductor device 2A turns to an off-state. As described above, in the IGBT, when turning to the off-state, the accumulated carriers stay within the IGBT and IGBT may improperly operate. However, the improper operation is avoided by the following operation.

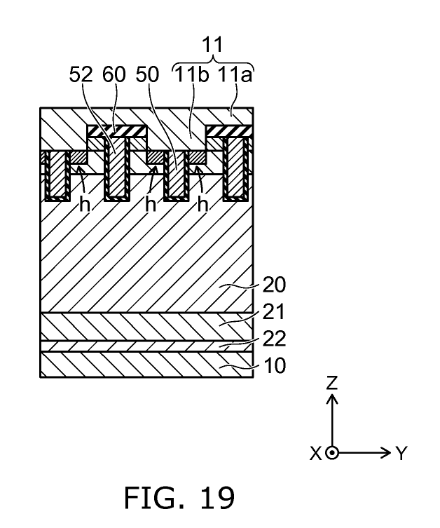

FIG. 19 is a schematic sectional view showing an example of an operation immediately after the turn-off of the semiconductor device according to the second embodiment.

FIG. 19 corresponds to FIG. 17A.

In the semiconductor device 2A, the contact region 32 is provided immediately below the portion 11b of the emitter electrode 11.

In FIG. 19, holes (h) flow into the contact region 32 immediately after the turn-off (arrows in FIG. 19). Then, the holes (h) flowing into the contact region 32 are ejected via the contact region 32 to the emitter electrode 11 immediately above.

As described above, in the semiconductor device 2A, the holes (h) are rapidly ejected to the emitter electrode 11 immediately after the turn-off. Thereby, in the semiconductor device 2A, the operation of the parasitic npn-transistor after turn-off is suppressed and latch-up is harder to occur. As a result, the semiconductor device 2A has high breakdown withstand capability.

Further, the electrode 50 is connected to the emitter electrode 11 and, in either of the on-state or the off-state, the potential does not vary, but the stable potential is maintained.

As described above, according to the second embodiment, the highly reliable semiconductor device 2A is provided.

### (First Variation of Second Embodiment)

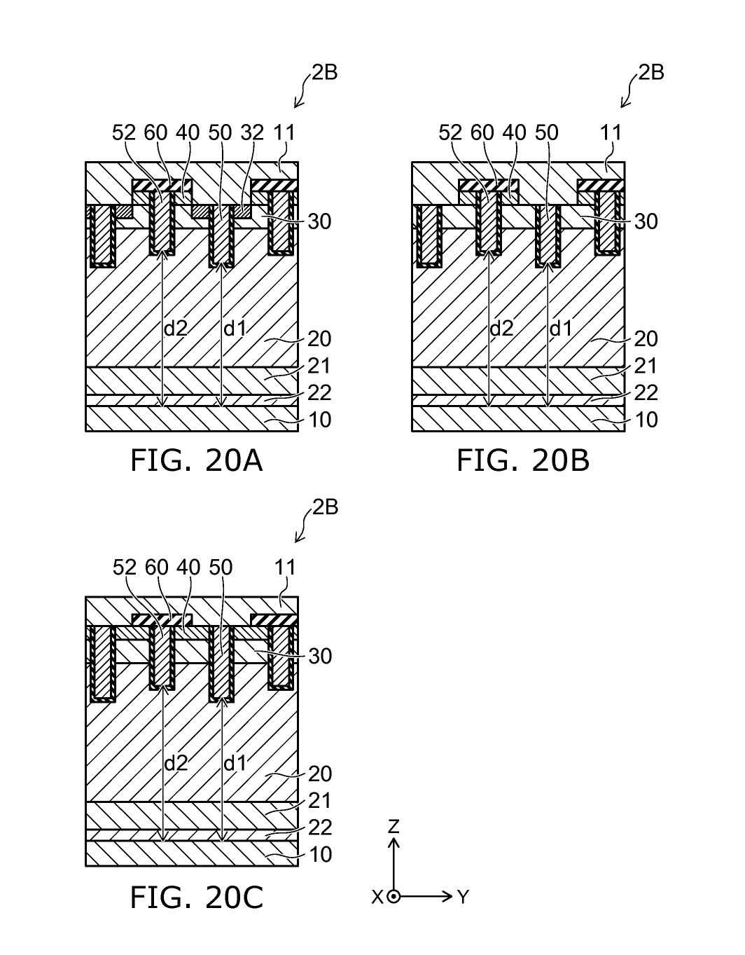

FIGS. 20A to 20C are schematic sectional views of a semiconductor device according to a first variation of the second embodiment.

Here, the positions of the sections in the respective drawings of FIGS. 20A to 20C correspond to the positions of the sections in the respective drawings of FIGS. 17A to 17C, respectively.

In a semiconductor device 2B, a distance d1 between the collector electrode 10 and the electrode 50 and a distance d2 between the collector electrode 10 and the gate electrode 52 are different. For instance, the distance d1 is shorter than the distance d2.

According to the structure, the electric fields are more liable to concentrate on the lower end of the electrode 50 than on the lower end of the gate electrode 52 and avalanche occurs more preferentially on the lower end of the electrode 50 than on the lower end of the gate electrode 52. Further, the portion 11a and the portion 11b of the emitter electrode 11 are located immediately above the electrode 50.

Therefore, the carriers (e.g. holes) generated by avalanche are ejected more efficiently via the portion 11a and the portion 11b of the emitter electrode 11. Thereby, the breakdown withstand capability of the semiconductor device 2B is further improved compared to that of the semiconductor device 2A.

### (Second Variation of Second Embodiment)

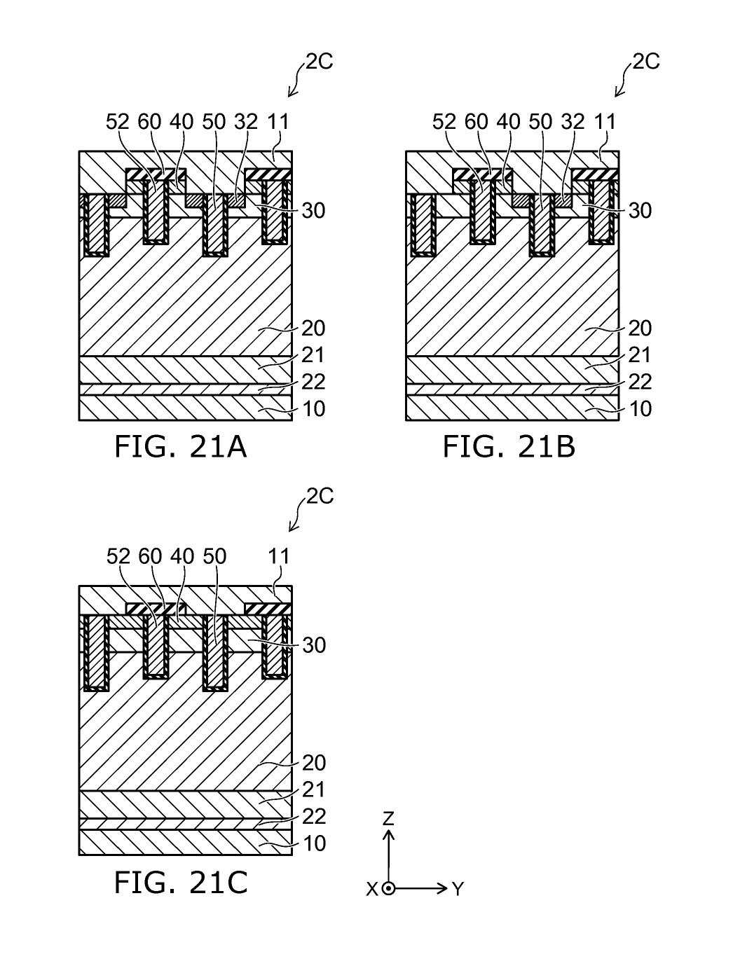

FIGS. 21A to 21C are schematic sectional views of a semiconductor device according to a second variation of the second embodiment.

Here, the positions of the sections in the respective drawings of FIGS. 21A to 21C correspond to the positions of the sections in the respective drawings of FIGS. 17A to 17C, respectively.

In a semiconductor device 2C, also in the cross section shown in FIG. 21B, the contact region 32 is provided between the base region 30 and the emitter electrode 11.

Therefore, immediately after the turn-off, the holes (h) may be ejected also from the contact region 32 shown in FIG. 21B to the emitter electrode 11. Thereby, the semiconductor device 2C has the higher breakdown withstand capability. Note that the distance d1 between the collector electrode 10 and the electrode 50 and the distance d2 between the collector electrode 10 and the gate electrode 52 may be the same.

### (Third Variation of Second Embodiment)

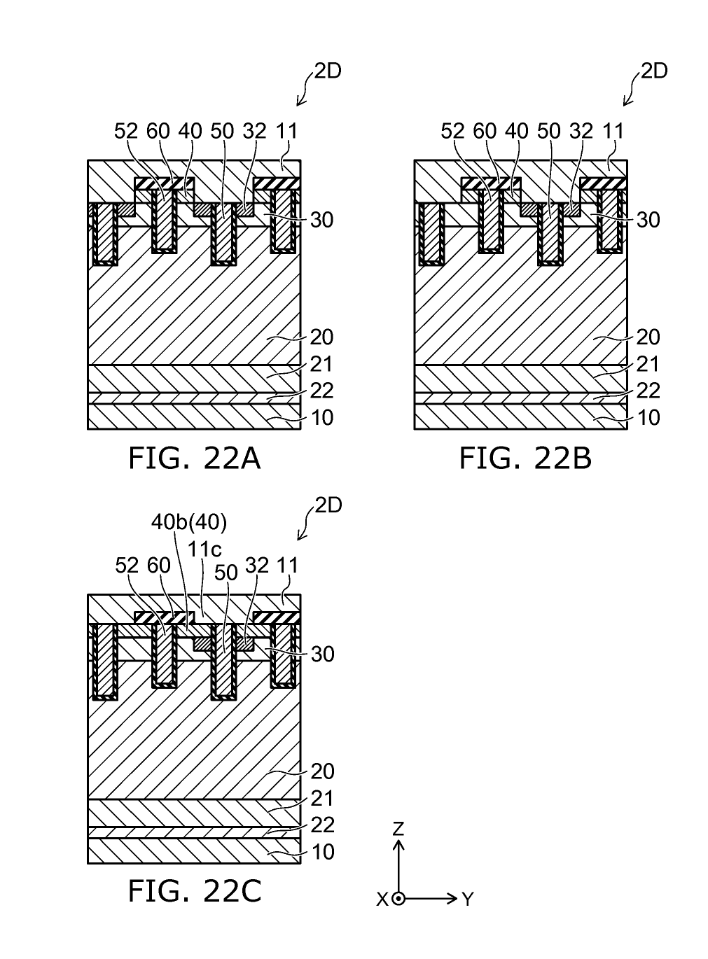

FIGS. 22A to 22C are schematic sectional views of a semiconductor device according to a third variation of the second embodiment.

Here, the positions of the sections in the respective drawings of FIGS. 22A to 22C correspond to the positions of the sections in the respective drawings of FIGS. 17A to 17C, respectively.

In a semiconductor device 2D, in the cross section shown in FIG. 22C, the contact region 32 is provided between the base region 30 and the portion 11c of the emitter electrode 11. For instance, the contact region 32 is provided between the base region 30 and the second region 40b of the emitter region 40. That is, the contact region 32 continuously extends in the X-direction.

Therefore, immediately after the turn-off, the holes (h) may be ejected via the contact region 32 shown in FIGS. 22A to 22C to the emitter electrode 11. Thereby, the semiconductor device 2D has the higher breakdown withstand capability. Note that the distance d1 between the collector electrode 10 and the electrode 50 and the distance d2 between the collector electrode 10 and the gate electrode 52 may be the same.

The embodiments include a structure in which the collector region 22 at the collector side is removed from the IGBT for changing the IGBT to a power MOSFET (Metal Oxide Semiconductor Field Effect Transistor). Here, when the IGBT is changed to the power MOSFET, the above described collector is read as a drain and the emitter is read as a source.

In the embodiments described above, the term “on” in “a portion A is provided on a portion B” may refer to not only the case where the portion A is provided on the portion B such that the portion A is in contact with the portion B but also the case where the portion A is provided above the portion B such that the portion A is not in contact with the portion B. Furthermore, “a portion A is provided on a portion B” may refer to the case where the portion A and the portion B are inverted and the portion A is located below the portion B and the case where the portion A and the portion B are laterally juxtaposed. This is because, even when the semiconductor device according to the embodiment is rotated, the structure of the semiconductor device is not changed by the rotation.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first electrode;
a second electrode having a portion extending toward the first electrode side;
a first semiconductor layer of a first conductivity type provided between the first electrode and the second electrode;
a first semiconductor region of a second conductivity type provided between the first semiconductor layer and the second electrode;
a second semiconductor region of the first conductivity type provided between the first semiconductor region and the second electrode, and the second semiconductor region being in contact with the portion;
a third electrode provided between the first electrode and the portion, the third electrode being provided on the first semiconductor layer, the first semiconductor region, and the second semiconductor region via a first insulating film, and the third electrode being connected to the portion;
a fourth electrode provided on the first semiconductor layer, the first semiconductor region, and the second semiconductor region via a second insulating film; and
a third semiconductor region of the second conductivity type provided between the first semiconductor region and the second semiconductor region, and the third semiconductor region having a higher impurity concentration than the first semiconductor region.

2. The device according to claim 1, wherein the second semiconductor region is provided between the third semiconductor region and the portion.

3. The device according to claim 1, wherein the portion is in contact with the third semiconductor region.

4. The device according to claim 1, further comprising:
a fourth semiconductor region of the second conductivity type provided between the first semiconductor region and the second electrode, the fourth semiconductor region being in contact with the portion, and the fourth semiconductor region having a higher impurity concentration than the first semiconductor region,
wherein the second semiconductor region and the fourth semiconductor region are alternately arranged in a direction crossing a direction from the first electrode toward the second electrode, and
the third semiconductor region continuously extends in the direction of the alternate arrangement.

5. The device according to claim 4, wherein the portion continuously extends in the direction of the alternate arrangement.

6. The device according to claim 1, further comprising:
a fourth semiconductor region of the second conductivity type provided between the first semiconductor region and the second electrode, the fourth semiconductor region being in contact with the portion, and the fourth semiconductor region having a higher impurity concentration than the first semiconductor region,
wherein the fourth semiconductor region is provided between the third semiconductor region and the portion.

7. The device according to claim 1, further comprising:
a fourth semiconductor region of the second conductivity type provided between the first semiconductor region and the second electrode, the fourth semiconductor region being in contact with the portion, and the fourth semiconductor region having a higher impurity concentration than the first semiconductor region,
wherein the third semiconductor region is provided between the first semiconductor region and the fourth semiconductor region.

8. The device according to claim 1, wherein the third semiconductor region is in contact with the first insulating film.

9. The device according to claim 1, wherein the third semiconductor region is provided below the portion.

10. The device according to claim 1, wherein a distance between the portion and the first electrode is shorter than a distance between an upper portion of the second semiconductor region and the first electrode.

11. The device according to claim 1, further comprising:
a fifth semiconductor region of the second conductivity type between the first semiconductor layer and the first electrode.

12. A semiconductor device comprising:
a first electrode;
a second electrode having a first portion extending toward the first electrode side and a second portion having a thickness smaller than a thickness of the first portion;
a first semiconductor layer of a first conductivity type provided between the first electrode and the second electrode;
a first semiconductor region of a second conductivity type provided between the first semiconductor layer and the second electrode;
a second semiconductor region of the first conductivity type provided between the first semiconductor region and the second electrode, and the second semiconductor region connected to the first portion and the second portion;
a third electrode provided between the first electrode and the first portion and between the first electrode and the second portion, the third electrode being provided on the first semiconductor layer and the first semiconductor region via a first insulating film, and the third electrode being connected to the first portion and the second portion;
a fourth electrode provided on the first semiconductor layer, the first semiconductor region, and the second semiconductor region via a second insulating film; and
a third semiconductor region of the second conductivity type provided between the first semiconductor region and the first portion, and the third semiconductor region having a higher impurity concentration than the first semiconductor region.

13. The device according to claim 12, wherein the third semiconductor region is provided between the first semiconductor region and the second portion.

14. The device according to claim 12, wherein a distance between the first electrode and the third electrode and a distance between the first electrode and the fourth electrode are different.

15. The device according to claim 12, wherein a distance between the first electrode and the third electrode is shorter than a distance between the first electrode and the fourth electrode.

16. The device according to claim 12, wherein the third semiconductor region is in contact with the first insulating film.

17. The device according to claim 12, wherein the third semiconductor region is provided below the first portion or below the second portion.

18. The device according to claim 12, wherein a distance between the portion and the first electrode is shorter than a distance between an upper portion of the second semiconductor region and the first electrode.

19. The device according to claim 12, further comprising:
a fifth semiconductor region of the second conductivity type between the first semiconductor layer and the first electrode.

20. A method of manufacturing a semiconductor device comprising:
preparing a structure in which a first semiconductor region of a second conductivity type is provided in a surface layer of a semiconductor layer of a first conductivity type, a second semiconductor region of the first conductivity type is selectively provided in a surface layer of the first semiconductor region, a third electrode in contact with the semiconductor layer, the first semiconductor region, and the second semiconductor region via a first insulating film and a fourth electrode in contact with the first semiconductor layer, the first semiconductor region, and the second semiconductor region via a second insulating film are provided;
forming an interlayer insulating film covering the fourth electrode, the second insulating film, and part of the second semiconductor region sandwiching the fourth electrode and opening the third electrode, the first insulating film, and another portion of the second semiconductor region than the part on the second semiconductor region and on the fourth electrode;
forming a trench having the third electrode, the first insulating film, and the portion of the second semiconductor region as a bottom portion by etching the third electrode, the first insulating film, and the portion of the second semiconductor region opened from the interlayer insulating film; and
forming a third semiconductor region of the second conductivity type between the first semiconductor region and the second semiconductor region by introducing an impurity element of the second conductivity type into a side of the semiconductor layer via the trench.
